(19) United States
(12) Patent Application Publication
(10) Pub. No.: US 2006/0044162 A1
(43) Pub. Date: Mar. 2, 2006

(54) FIBRE OPTIC COMMUNICATIONS

(75) Inventors: Sebastian Fenn, Gloucester (GB); Allard Van Der Horst, Gwent (GB); Francisco Alcala, Bristol (GB); Peter Sweeney, Guildford (GB); Nicholas H. Weiner, Bristol (GB)

Correspondence Address: LAHIVE & COCKFIELD, LLP., 28 STATE STREET, BOSTON, MA, 02109, US

(73) Assignee: Phyworks Limited, Bristol (GB)

(21) Appl. No.: 10/353,305

(22) Filed: Jan. 29, 2003

(30) Foreign Application Priority Data
Dec. 27, 2002 (GB) 0230216.4

(51) Int. Cl. H03M 7/00

(52) U.S. Cl. 341/50

(57) ABSTRACT

An encoder and an encoding method are suitable for use in an optical communication system. A concatenated coding scheme is used, in which the source data are encoded by means of an outer encoder to produce outer encoded data, and the outer encoded data are encoded by means of an inner encoder to produce inner encoded data, which are transmitted over a communications medium, such as an optical fibre. The inner encoder acts to produce inner encoded data in a format which occupies the space occupied one or more (for example, two) frames as defined in a standard, in this case the ITU-T G.709 standard. The inner encoder forms a product code from two sets of codewords, for example Extended Hamming codes. More particularly, at least one of the two sets of codewords is a shortened code, in order that the inner encoded data exactly occupies a plurality of frames as defined in the standard.

### TECHNICAL FIELD OF INVENTION

This invention relates to fibre optic communications, and in particular to a method and a device for encoding data for transmission over a fibre optic transmission line, and to a method and a device for decoding data after transmission over a fibre optic transmission line.

### BACKGROUND OF THE INVENTION

A fibre optic communications protocol is defined in the ITU-T Recommendation G.709. This defines a frame structure for the optical channel, in which each frame contains a prescribed number of bits of management data, a prescribed number of bits of actual payload data, and a prescribed number of bits for forward error correction.

Forward error correction (FEC) is a conventional technique for maintaining acceptable performance in data communications networks. In essence, additional coded bits are added to data before transmission over a communications medium, and these additional bits can be used in the receiver to identify the presence of errors in the received data and to correct those errors.

Different forward error correction techniques are known, and the different techniques have different abilities to identify and correct errors.

The ITU-T G.709 standard is defined with reference to one well-known forward error correction scheme, namely the Reed-Solomon RS(255,239) code. In this coding scheme, each group of 239 bytes of useful data is accompanied by an additional 16 bytes of data (making 255 bytes in total) for error correction. In the ITU-T G.709 standard, the useful data consists of the management data and the payload data. Each G.709 frame contains 64 of these blocks.

The ITU-T G.709 standard does not make the use of the RS(255,239) coding scheme compulsory, and it would be advantageous to use a coding scheme with improved error correction performance. However, different coding schemes will in general produce data for transmission over the communications medium at different data rates. This will mean that a receiver, which is designed for good performance with the RS(255,239) coding scheme, will perform less well with an alternative scheme.

### SUMMARY OF THE INVENTION

According to the present invention, there are provided a method and a transmitter for use in an optical communications system. A concatenated coding scheme is used, in which the source data are encoded by means of an outer encoder to produce outer encoded data, and the outer encoded data are encoded by means of an inner encoder to produce inner encoded data, which are transmitted over a communications medium, such as an optical fibre. The inner encoder acts to produce inner encoded data in a format which occupies the space occupied by a plurality of frames as defined in a standard, in this case the ITU-T G.709 standard.

In one preferred embodiment, the encoded data occupies two ITU-T G.709 standard frames, although any number of frames could be used.

Preferably, the inner encoder forms a product code from two sets of codewords, and in a preferred embodiment the inner encoder forms a product of extended hamming codes. More particularly, at least one of the two sets of codewords is a shortened code, in order that the inner encoded data exactly occupies a plurality of frames as defined in the standard.

According to another aspect of the invention, there are provided a corresponding decoder and a method of decoding received data.

### BRIEF DESCRIPTION OF DRAWINGS

FIG. 1 is a block schematic diagram of a communications system in accordance with the invention.

FIG. 2 shows the structure of two data frames.

### DETAILED DESCRIPTION OF PREFERRED EMBODIMENTS

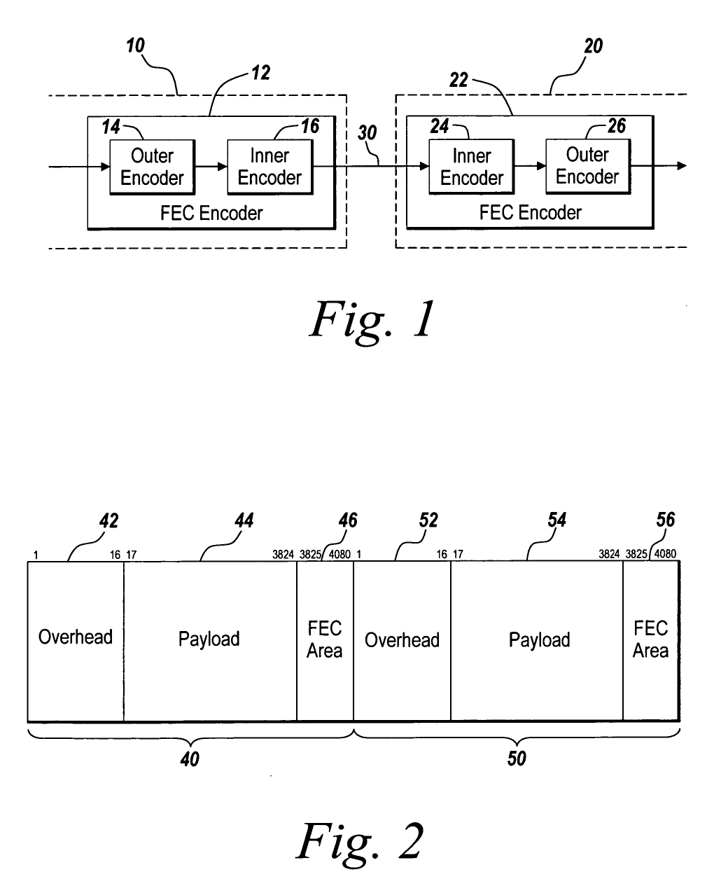

FIG. 1 is a block schematic diagram of a communications system in accordance with the present invention. Source data, which are intended for transmission from a first device 10 to a second device 20, are received in a forward error correction (FEC) encoder 12 within the first device 10. As will be described in more detail below, the FEC encoder 12 is a concatenated encoder, which means that it includes an outer encoder 14, which encodes the source data to form outer encoded data, and an inner encoder 16, which further encodes the outer encoded data to form inner encoded data.

The inner encoded data is passed over a communications medium, which in this case is an optical fibre 30.

After transfer over the optical fibre 30, the data are received in a FEC decoder 22 within the second device 20. Since the FEC encoder 12 is a concatenated encoder, the FEC decoder 22 is a concatenated decoder, which includes an inner decoder 24, which decodes the inner encoded data to form inner decoded data, and an outer decoder 26, which decodes the inner decoded data to form outer decoded data.

FIG. 2 shows the structure of two data frames 40, 50, formed in accordance with the ITU-T G.709 standard. Each of the frames 40, 50 includes a respective area 42, 52 containing overhead information, an area 44, 54 containing the payload data, and a FEC area 46, 56, containing the forward error correction bits.

The ITU-T G.709 standard is defined with reference to the well-known Reed-Solomon RS(255,239) forward error correction scheme. In this coding scheme, each group of 239bytes of source data (including overhead data and payload data in this case) is accompanied by an additional 16 bytes of data (making 255 bytes in total) for error correction. Each G.709 frame contains 64 of these blocks, that is, 16320 bytes, with the data arranged in four rows and 4080 columns. Thus, the areas 42, 52 containing overhead information occupy columns 1-16 of all four rows giving a total of 64 bytes, and the payload data areas 44, 54 occupy columns 17-3824 of all four rows giving a total of 15232 bytes, so that there are 15296 bytes (that is 64 blocks of 239bytes) of source data in each frame. The FEC areas 46, 56 containing the forward error correction bits occupy columns 3825-4080 of all four rows giving a total of 1024 bytes (that is 64 blocks of 16 bytes) of FEC data in each frame.

The ITU-T G.709 standard also defines three specific frame rates, that is, frequencies at which frames may be transmitted over the communications medium. With a known number of bytes of data in a frame, each of these frame rates corresponds to a specific line rate, that is a rate (in gigabits per second, for example) at which data is transferred over the communications medium.

As mentioned above, the ITU-T G.709 standard is defined with reference to the Reed-Solomon RS(255,239) forward error correction scheme. As a result, some devices are designed for optimal performance with the parameters which result from the use of this error correction scheme. For example, the devices may include clock synthesizers which can be used to clock data onto the communications medium at one or more of the line rates which result from use of the RS(255,239) forward error correction scheme. As another example, the devices may include transmission components which are optimised for one or more of these line rates.

An advantage of the present invention, therefore, is that it generates data at a line rate which is the same as the line rate which results from the use of the RS(255,239) scheme. In accordance with the preferred embodiment of the invention, this is achieved by choosing an inner coding scheme which produces exactly the same amount of data as the RS(255,239) scheme. This in turn is made easier by choosing an inner coding scheme which is a product code, formed from a product of two codes, one or more of which may be a shortened code, so that the coding scheme produces the required amount of data.

One well-known category of FEC codes is the set of Extended Hamming codes. An Extended Hamming code can be summarised as a set of 2ⁿ−n−1 data bits (for some integer n) together with an n-bit parity code and a parity check bit.

A two-dimensional product of such Extended Hamming codes comprises the source data bits, arranged as a rectangular array, together with the parity code and a check bit for each row and each column.

It is also known that FEC codes may be shortened, before transmission, by reducing the number of data bits transmitted, while the number of parity bits is unchanged, and these are computed as if the untransmitted bits are all of a constant value (usually zero). The corresponding FEC decoder in the receiver acts on the received bits as if the untransmitted bits were also received, with the known constant values.

An Extended Hamming code can be defined, for which, using the notation above, n=9. This Extended Hamming Code is of size 512 bits, of which 502 bits are data bits, and 10 bits are parity bits. This code is referred to as the Extended Hamming Code (512,502). A shortened Extended Hamming Code can be defined by not transmitting two of the data bits, giving 510 bits, of which 500 bits are data bits, and 10 bits are parity bits. This code is referred to as the shortened Extended Hamming Code (510,500).

The product of these two codes is referred to as the Extended Hamming Product Code (512×510, 502×500), and has size (512×510) bits, or 32640 bytes, of which (502×500) bits, that is 251000 bits, or 31375 bytes, are data bits.

It will be noted that the size of this Extended Hamming Product Code, namely (512×510) bits, is exactly the same as the size of two standard ITU-T G.709 frames.

Therefore, in the preferred embodiment of the invention, the inner encoder 16 forms the Extended Hamming Product Code (512×510, 502×500) from the outer encoded data, and the resulting inner encoded data occupies the same space as two standard ITU-T G.709 frames.

In order for this to be possible, the outer encoder 14 must be able to process the source data from two standard ITU-T G.709 frames in such a way as to produce outer encoded data which can be encoded by the inner encoder 16 in this way. More specifically, the outer encoder 14 must process two ITU-T G.709 frames of payload and management overhead data in such a way that it produces a smaller number of outer encoded data bits than the number of data bits in one Extended Hamming Product Code (512×510, 502×500) frame.

Advantageously, the outer encoder 14 forms an interleave of multiple frames of another known FEC coding scheme, for example using Reed-Solomon or BCH codes. Such interleaving, which is a well-known technique in itself, makes the coding more robust against burst errors and inner decoding errors.

In the preferred embodiment of the invention, the outer encoder 14 uses the known Reed Solomon RS 2¹¹ code, RS(1901, 1855). Using this FEC scheme, each block of 11×1855 bits of data is encoded into codewords comprising 11×1901 output bits. Thus, twelve frames of RS(1901, 1855) coding can handle 12×11×1855 bits of data. This is equivalent to 30607.5 bytes of data, and so it is sufficient to handle the 30592 bytes of source data in two ITU-T G.709 frames. Further, twelve frames of RS(1901, 1855) coding produce 12×11×1901 bits of outer encoded data. This is equivalent to 31366.5 bytes of data, and so, since this is less than the number of data bits in the Extended Hamming Product Code (512×510, 502×500), this data can be processed by the inner encoder 16 as described above.

After inner encoding in the inner encoder 16, the data can be transmitted in a format which is similar to that used in the ITU-T G.709 format. Thus, one block of data has the same size as two ITU-T G.709 frames.

The use of concatenated coding, as described in the preferred embodiment of the invention, has the advantage that the error correction performance of the overall coding scheme is improved, compared with that of the RS(255,239) coding scheme, while the data can be transmitted in frames which are compatible with ITU-T G.709 default frames, and can therefore take full advantage of any features of the transmitter and receiver which are optimised for use with that standard.

It will be appreciated that other coding schemes can also be used. In particular, other outer encoding schemes which have sufficient capacity to handle the source data in two ITU-T G.709 frames, while producing less outer encoded data than the number of data bits in the used Extended Hamming Product Code, are possible. Further, although a coding scheme has been described in which the inner encoding scheme produces inner encoded data which fit exactly into two ITU-T G.709 frames, other inner encoding schemes are also possible, in particular inner encoding schemes which produce inner encoded data which fit exactly into some other integer multiple of an ITU-T G.709 frame.

It is also possible to choose a coding scheme which produces inner encoded data which do not fit exactly into the ITU-T G.709 frame (or frames), but which are sufficiently close in size that the remaining space can be filled by unused data without significantly reducing the efficiency of the coding scheme.

The same principle can also be applied to other standards. That is, where a frame is defined with reference to a coding scheme, it is possible to define an alternative concatenated coding scheme, which produces encoded data in the format specified in the standard. In particular, this is made easier if the concatenated coding scheme uses a product code, where one or more of the codes is a shortened code.

When the transmitted data are received in the decoder 22, the data are extracted from the frames, and corresponding decoding steps are performed, using the appropriate decoding algorithms.

Thus, the inner decoder 24 carries out a decoding step which is the inverse of the inner encoding step, and the outer decoder 26 carries out a decoding step which is the inverse of the outer encoding step.

There are therefore disclosed methods and devices for encoding and decoding data, which can fully utilise the features of devices optimised for use in the ITU-T G.709 standard, but which can provide improved error correction.

1-38. (canceled)

39. A method of encoding data, comprising:
encoding source data by means of an outer encoder to produce outer encoded data,
encoding the outer encoded data by forming a product code of Extended Hamming codewords to produce inner encoded data in a format which occupies 32640 bytes, and
transmitting the inner encoded data over a communications medium.

40. An encoder, comprising:
an outer encoder, for encoding source data to produce outer encoded data,
an inner encoder, for encoding the outer encoded data by forming a product code of
Extended Hamming codewords to produce inner encoded data in a format which occupies 32640 bytes.

41. A method of decoding data, comprising:
receiving encoded data over a communications medium in a format which occupies 32640 bytes, wherein the encoded data comprises a product code of Extended Hamming codewords;
decoding the received data by means of an inner decoder to produce inner decoded data; and
decoding the inner decoded data to produce outer decoded data.

42. A decoder, comprising:
an inner decoder, for receiving encoded data over a communications medium in a format which occupies 32640 bytes, wherein the encoded data comprises a product code of Extended Hamming codewords, and for decoding the received data to produce inner decoded data; and
an outer decoder, for decoding the inner decoded data to produce outer decoded data.
